(19) United States
(12) Patent Application Publication
(10) Pub. No.: US 2026/0250838 A1
(43) Pub. Date: Aug. 27, 2026

(54) COMPOSITIONS FOR DEPOSITING MATERIAL, SYNTHESIS METHODS AND USES

(71) Applicant: ASM IP Holding B.V., Almere (NL)

(72) Inventors: Charles Dezelah, Helsinki (FI); Craig Wheaton, Kingston (CA); Qi Xie, Wilsele (BE)

(21) Appl. No.: 19/644,362

(22) Filed: Apr. 10, 2026

Related U.S. Application Data
(63) Continuation of application No. 17/562,114, filed on Dec. 27, 2021, now Pat. No. 12,630,919.
(60) Provisional application No. 63/131,853, filed on Dec. 30, 2020.

(51) Int. Cl. C23C 16/18; C23C 16/54

(52) U.S. Cl. CPC C23C 16/18; C23C 16/54

(57) ABSTRACT

The current disclosure relates to a composition for depositing group 13 metal-containing material on a substrate. The composition comprises a metal alkyl precursor, wherein the metal alkyl precursor comprises a group 13 metal atom and two different alkyl ligand types. The first ligand type is a branched C4 to C8 alkyl bonded to the group 13 metal atom through a carbon atom that is bonded to three carbon atoms, and the second ligand type is a linear C1 to C4 alkyl. The group 13 metal atom is bonded to two ligands of the first ligand type, and the ratio of first ligand type to second ligand type in the composition is about two to one. Further, the disclosure relates to methods of manufacture of compositions and their uses, as well as methods of depositing material on a substrate.

### CROSS-REFERENCE TO RELATED APPLICATIONS

This application is a continuation of, and claims priority to, U.S. patent application Ser. No. 17/562,114 filed Dec. 27, 2021 titled COMPOSITIONS FOR DEPOSITING MATERIAL, SYNTHESIS METHODS AND USES; which claims priority to U.S. Provisional Patent Application Ser. No. 63/131,853 filed Dec. 30, 2020 titled COMPOSITIONS FOR DEPOSITING MATERIAL, SYNTHESIS METHODS AND USES, the disclosures of which are hereby incorporated by reference in their entirety.

### FIELD

The present disclosure generally relates to compositions for depositing a metal precursor to form a metal-containing layer on a substrate. Further, the disclosure relates to methods of manufacture of compositions and their uses, as well as methods of depositing material on a substrate.

### BACKGROUND

Group 13 metals, especially aluminum, gallium and indium are used in various applications for the production of semiconductor devices. One example are metal-containing thin films for work function tuning applications. The selection of suitable metal precursor compounds is critical for successful deposition and material performance. Such metal compounds require a specific combination of physical and chemical properties for them to be useful for producing a film that possesses the desired composition, resistivity, and effective work function.

Alkyl metal compounds are attractive precursors in vapor deposition. However, to find suitable precursors, having an appropriate combination of volatility, reactivity and stability for use in demanding deposition applications is challenging. Therefore, there is need in the art for improved metal precursors to deposit thin films for the manufacture of semiconductor devices.

### SUMMARY

The current invention describes metal precursor compositions and methods of producing them. In a first aspect, a composition for depositing group 13 metal-containing material on a substrate is disclosed. The composition comprises a metal alkyl precursor, comprising a group 13 metal atom and two different alkyl ligand types. The first ligand type is a branched C4 to C8 alkyl bonded to the group 13 metal atom through a carbon atom that is bonded to three carbon atoms, the second ligand type is a linear C1 to C4 alkyl and the group 13 metal atom is bonded to two ligands of the first ligand type. In the composition according to the current disclosure the ratio of first ligand type to second ligand type is about two to one.

In a second aspect, a method of producing a composition according to the current disclosure is disclosed, wherein the method comprises reacting bis(methyl)tert-butylaluminum with aluminumtrichloride and tert-butyllithium to obtain bis(tert-butyl)methylaluminum.

In a third aspect, a method of producing a composition according to the current disclosure is disclosed, wherein the method comprises reacting trimethylaluminum with aluminumtrichloride and tert-butyllithium to obtain bis(tert-butyl)methylaluminum.

In a fourth aspect, a method of producing a composition according to the current disclosure, wherein the method comprises reacting tri(tert-butyl)aluminum with trimethylaluminum to obtain bis(tert-butyl)methylaluminum.

In a fifth aspect, a method of depositing group 13 metal-containing material on a substrate using the composition according to the current disclosure is disclosed.

In a sixth aspect, use of a composition according to the current disclosure to deposit a group 13 metal-containing material on a substrate is disclosed.

In a seventh aspect, a chemical reactant vessel containing a composition according to the current disclosure is disclosed.

In an eighth aspect, ac vapor deposition assembly comprising a reactant vessel according to the current disclosure is disclosed.

Mixed alkyl compounds of metals are used as precursors for semiconductor applications. They may be more stable than some of the homoleptic metal alkyl precursors, while having sufficient reactivity for sensitive deposition applications. However, the different ligands are often susceptible to ligand redistribution reactions hampering the use of mixed-ligand compounds as precursors in demanding applications. The compositions according to the current disclosure may provide stability against ligand redistribution observed in other mixed alkyl metal compounds. Such redistribution observed in many mixed-ligand alkyl precursors may lead to the formation of multiple undesired by-products under dynamic evaporation conditions typical of vapor phase precursor delivery from a condensed phase source compound. Since these by-products differ in volatility, their relative concentration in the precursor source container can vary significantly over time and substantial process drift often results.

The current disclosure provides compositions that have unexpected stability against isomerization reactions that are common for metal complexes containing bulky alkyl ligands containing, for example, branched alkyl groups. Both of the above types of stability may improve the vapor deposition properties of the compositions according to the current disclosure. Additionally, the stability may promote atomic layer deposition (ALD)-type growth of the desired films with reduced self-decomposition, increased metal incorporation, and reduced process drift.

### BRIEF DESCRIPTION OF DRAWINGS

The accompanying drawings, which are included to provide a further understanding of the disclosure and constitute a part of this specification, illustrate exemplary embodiments, and together with the description help to explain the principles of the disclosure. In the drawings

FIG. 1 illustrates a chemical reactant vessel according to the current disclosure.

FIG. 2 illustrates a vapor deposition assembly comprising a reactant vessel according to the current disclosure.

### DETAILED DESCRIPTION OF EXEMPLARY EMBODIMENTS

The description of exemplary embodiments of compositions, methods and uses provided below is merely exemplary and is intended for purposes of illustration only. The following description is not intended to limit the scope of the disclosure or the claims. Moreover, recitation of multiple embodiments having stated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising” or “comprising”. In this disclosure, any defined meanings do not necessarily exclude ordinary and customary meanings in some embodiments.

In an aspect, a composition for depositing group 13 metal-containing material on a substrate is disclosed. The composition comprises a metal alkyl precursor, wherein the metal alkyl precursor comprises a group 13 metal atom and two different alkyl ligand types. The first ligand type is a branched C4 to C8 alkyl bonded to the group 13 metal atom through a carbon atom that is bonded to three carbon atoms. The second ligand type is a linear C1 to C4 alkyl. The group 13 metal atom is bonded to two ligands of the first ligand type, and the ratio of first ligand type to second ligand type in the composition is about two to one. However, in some aspects, it may be possible to utilize the compositions according to the current disclosure for depositing carbon-containing material on a substrate.

By a composition is herein meant a preparation of a chemical that may be used for vapor deposition applications. Generally, compositions need to be stable enough for allowing the storage and use over an extended period of times, for example, over several months. The precursor should withstand the deposition conditions to allow vapor transfer into a reaction chamber. Additionally, the vaporization rate of a precursor compound under predetermined conditions remains preferably constant. Some compositions may suffer from more than one substance being vaporized from the composition. If the substances differ in volatility, the composition may be enriched in less volatile substances over time. This can lead to a phenomenon called process drift: one or more of the deposition process parameters gradually changes over time as the chemical composition of the composition changes. The consequences of process drift may be detrimental in sensitive applications, and the tuning of the process to compensate for the drift may be expensive, difficult, or even impossible. A composition also needs to allow the vaporization of the precursor molecule so that it may be delivered to a deposition chamber for vapor deposition. Thus, the temperature and pressure ranges at which a precursor contained in the composition have to be suitable for vapor deposition.

The terms “precursor” and “reactant” are used interchangeably in the current disclosure, and can refer to molecules (compounds, or molecules comprising a single element) that participate in a chemical reaction that produces another compound. A precursor or a reactant typically contains portions that at least partly form the compound or element resulting from the chemical reaction in question. Such a resulting compound or element may be deposited on a substrate. However, a precursor or a reactant may be an element or a compound that is not incorporated into the resulting compound or element to a significant extent. In some embodiments, a reactant or a precursor may be a reductant.

The composition according to the current disclosure comprises a metal alkyl precursor which comprises a group 13 metal atom. In some embodiments, the group 13 metal is selected from a group consisting of aluminum, gallium and indium. In some embodiments, the group 13 metal is aluminum. In some embodiments, the group 13 metal is gallium. In some embodiments, the group 13 metal is indium.

The metal alkyl precursor according to the current disclosure comprises two different alkyl ligand types, the first ligand type and the second ligand type. Thus, each group 13 metal atom is bonded to two different kinds of ligands.

The first ligand type is a branched C4 to C8 alkyl bonded to the group 13 metal atom through a carbon atom that is bonded to three carbon atoms. In other words, the group 13 metal atom is bonded to a carbon atom, which again is attached to three carbon atoms (the three “branching carbon atoms”). Such alkyl ligands occupy a large space around the metal atom, and may create steric effects to reactions, and the spatial orientation of the atoms also may affect bond strengths. The first ligand type is an alkyl group containing from four to eight carbon atoms, i.e. it is a C4 to C8 alkyl. It may thus contain four, five, six, seven or eight carbon atoms. Since the carbon atom being bonded to the metal atom is connected to three other carbon atoms, the smallest ligand of the first ligand type is a tert-butyl group. In some embodiments, the first ligand type is tert-butyl.

Any of the three branching carbon atoms may have one or more further carbon atoms attached to it. Often, there is one or two further carbon atoms attached to a branching carbon atom.

In some embodiments, one or two of the three branching carbon atoms has one or more further carbon atoms attached to it. In some embodiments, all three of the branching carbon atoms have further carbon atoms attached to them. In some embodiments, the first ligand type is a C4 or C5 alkyl. In such embodiments, one of the branching carbon atoms has one additional carbon atom attached to it. In some embodiments, the first ligand type is a C4 to C6 alkyl. In such embodiments, one branching carbon atom may have two further carbon atoms attached to it. Alternatively, two of the branching carbon atoms may have one further carbon atom attached to each branching carbon atom.

The group 13 metal atom is bonded to two ligands of the first ligand type. In some embodiments, both ligands of the first ligand type are identical. Having two identical ligands of the first ligand type may simplify the precursor synthesis process compared to having two different ligands of the first ligand type in the metal alkyl precursor.

In some embodiments, first ligand type is a saturated hydrocarbon. In some embodiments, second ligand type is a saturated hydrocarbon. In some embodiments, first ligand type and second ligand type are saturated hydrocarbons. In some embodiments, the first ligand type may comprise one or more double bonds. In some embodiments, the two ligands of the first ligand type form a substituted metallacycle with the group 13 metal atom. The metallacycle may be, for example, a substituted metallacyclobutane, substituted metallacyclopentane or substituted metallacyclohexane.

The second ligand type is a linear C1 to C4 alkyl. Thus, the second ligand type is smaller than the first ligand type. In some embodiments, the second ligand type is methyl or ethyl. In some embodiments, the second ligand is propyl. In some embodiments, the second ligand type is butyl. The composition of claim 1, wherein the first ligand type is tert-butyl and the second ligand type is methyl. In some embodiments, the first ligand type is tert-butyl and the second ligand type is ethyl. In some embodiments, the first ligand type is tert-butyl and the second ligand type is propyl.

In some embodiments, the first ligand type is 1,1-dimethylpropyl and the second ligand type is methyl. In some embodiments, the first ligand type is 1,1-dimethylpropyl and the second ligand type is ethyl. In some embodiments, the first ligand type is 1,1-dimethylpropyl and the second ligand type is propyl. In some embodiments, the first ligand type is 1,1-dimethylpropyl and the second ligand type is butyl.

In some embodiments, the first ligand type is 1-ethyl-1-methylpropyl and the second ligand type is methyl. In some embodiments, the first ligand type is 1-ethyl-1-methylpropyl and the second ligand type is ethyl. In some embodiments, the first ligand type is 1-ethyl-1-methylpropyl and the second ligand type is propyl. In some embodiments, the first ligand type is 1-ethyl-1-methylpropyl and the second ligand type is butyl.

In some embodiments, the first ligand type is 1,1-diethylpropyl and the second ligand type is methyl. In some embodiments, the first ligand type is 1,1-diethylpropyl and the second ligand type is ethyl. In some embodiments, the first ligand type is 1,1-diethylpropyl and the second ligand type is propyl. In some embodiments, the first ligand type is 1,1-diethylpropyl and the second ligand type is butyl.

In a composition according to the current disclosure, the ratio of first ligand type to second ligand type in the composition is about two to one. Thus, for each group 13 metal atom, there are approximately two ligands of the first ligand group, and one ligand of the second ligand group.

In some embodiments, the second ligand type may be a hydrogen. Thus, a composition for depositing group 13 metal-containing material on a substrate according to the current disclosure may comprise a metal alkyl precursor, wherein the metal alkyl precursor comprises a group 13 metal atom and two different alkyl ligand types, wherein the first ligand type is a branched C4 to C8 alkyl bonded to the group 13 metal atom through a carbon atom that is bonded to three carbon atoms, and the second ligand type is a hydrogen. In the composition, the group 13 metal atom is bonded to two ligands of the first ligand type, and the ratio of first ligand type to second ligand type in the composition is about two to one.

The metal alkyl precursor according to the current disclosure may exist as a monomer (depicted as structure 1 below) or as a dimer (depicted as structure 2 below). In the structures, L1 indicates a first ligand type and L2 a second ligand type. In a solid composition, the metal alkyl precursor may exist predominantly as a dimer. In a gas, the metal alkyl precursor may be free to exchange between a monomer and a dimer, leading to a mixture of both forms. In gas phase, the metal alkyl precursor may thus be present as a mixture of dimer and monomer. The monomeric form may be prevalent in gas phase.

As visualized below, in both forms, each group 13 metal atom is bonded to two ligands of type 1, and the ratio of first ligand type to second ligand type is two to one. However, in the dimer, the group 13 metal atom is connected to two ligands of the second ligand type. In this configuration, the second ligand type may be characterized as a bridging ligand. Without limiting the current disclosure to any specific theory of the structure of the metal alkyl precursor, the M-L₂-M unit may be described a 3-center, 2-electron bond.

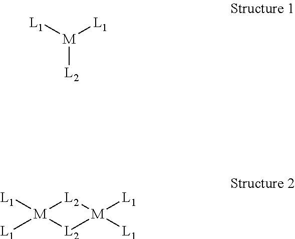

Without limiting the current disclosure to any specific theory, the dimer may be especially stable, making a solid composition comprising the metal alkyl precursor according to the current disclosure advantageous in vapor deposition processes. In some embodiments, at least 50% of the metal alkyl precursor is present as a dimer in the solid composition.

The metal alkyl precursor may be a precursor in a vapor deposition process. Thus, a composition according to the current disclosure may be used to deposit a group 13 metal—as metallic metal or as a compound with other elements—on a substrate.

A vapor deposition process according to the current disclosure may be a chemical vapor deposition (CVD) process. A vapor deposition process according to the current disclosure may be an atomic layer deposition (ALD) process. A vapor deposition process according to the current disclosure may be a cyclic vapor deposition process. As used herein, the term “cyclic deposition” may refer to the sequential introduction of precursors (reactants) into a reaction chamber to deposit a layer over a substrate, and includes processing techniques such as atomic layer deposition and cyclical chemical vapor position.

CVD-type processes typically involve gas phase reactions between two or more precursors or reactants. The precursors or reactants can be provided simultaneously to the reaction chamber or substrate, or in partially or completely separated pulses. The substrate and/or reaction space can be heated to promote the reaction between the gaseous reactants. In some embodiments the reactants are provided until a thin film having a desired thickness is deposited. Thus, a CVD-type process may be a cyclical process or a non-cyclical process. In some embodiments cyclical CVD-type processes can be used with multiple cycles to deposit a thin film having a desired thickness. In cyclical CVD-type processes, the reactants may be provided to the reaction chamber in pulses that do not overlap, or that partially or completely overlap.

ALD-type processes are based on controlled, typically self-limiting surface reactions of the precursor and/or reactant chemicals. Gas phase reactions are avoided by feeding the precursors alternately and sequentially into the reaction chamber. Vapor phase reactants are separated from each other in the reaction chamber, for example, by removing excess reactants and/or reactant by-products from the reaction chamber between reactant pulses. This may be accomplished with an evacuation step and/or with an inactive gas pulse or purge. In some embodiments the substrate is contacted with a purge gas, such as an inactive gas. For example, the substrate may be contacted with a purge gas between reactant pulses to remove excess reactant and reaction by-products. In some embodiments each reaction is self-limiting and monolayer by monolayer growth is achieved. These may be referred to as “true ALD” reactions. In some such embodiments a metal precursor may adsorb on the substrate surface in a self-limiting manner. A second reactant precursor or a reactant, and optional further reactants or precursors will react in turn with the adsorbed metal precursor to form up to a monolayer of metal or metal compound on the substrate.

The composition according to the current disclosure may be used to deposit group 13 metal-containing material on a substrate. As used herein, the term “substrate” can refer to any underlying material or materials that can be used to form, or upon which, a structure, a device, a circuit, or a layer can be formed. A substrate can include a bulk material, such as silicon (e.g., single-crystal silicon), other Group IV materials, such as germanium, or other semiconductor materials, such as a Group II-VI or Group Ill-V semiconductor materials, and can include one or more layers overlying or underlying the bulk material. Further, the substrate can include various features, such as recesses, protrusions, and the like formed within or on at least a portion of a layer of the substrate. For example, a substrate can include bulk semiconductor material and an insulating or dielectric material layer overlying at least a portion of the bulk semiconductor material.

The group 13 metal-containing material may be deposited as a layer or a thin film. As used herein, the term “layer” and/or “film” can refer to any continuous or non-continuous structure and material, such as material deposited by vapor deposition processes described herein. For example, layer and/or film can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous. A layer may be a seed layer. A seed layer may be a non-continuous layer serving to increase the rate of nucleation of another material. However, the seed layer may also be substantially or completely continuous.

The group 13 metal-containing material may be metallic (elemental) metal, such as aluminum metal, indium metal or gallium metal. In some embodiments, the group 13 metal is selected from a group consisting of aluminum, gallium and indium. Thus, the oxidation state of the metal may be 0. In some embodiments, oxidation state of the metal is other than zero. In some embodiments, the oxidation state may be, for example, +1 or +3. Deposited material, or a layer comprising deposited material, may comprise other elements or compounds that the metal deposited from the composition according to the current disclosure. In some embodiments, group 13 metal may be deposited to yield metal carbides, nitrides or oxides. For example, aluminum oxide, aluminum carbide or aluminum nitride, gallium oxide, gallium carbide or gallium nitride, indium oxide, indium carbide or indium nitride may be deposited. The current composition may also be used to deposit ternary materials comprising a group 13 metal, together with, for example silicon and oxide. Additionally, the composition according to the current disclosure may be used to deposit metal alloys, such as cobalt-aluminum, ruthenium-aluminum, molybdenum-aluminum or tungsten-aluminum.

The composition according to the current disclosure comprises a group 13 metal having two ligands of first ligand type and a ligand of second ligand type attached to it. Metal alkyl compounds comprising more than one type of ligand (i.e. mixed-alkyl metal compounds) are often susceptible to ligand redistribution, which may cause the formation of various undesired by-products in vapor deposition. Under such conditions, the most volatile substances will be vaporized preferentially, leading to process drift during the use of a given precursor batch. In other words, advantageous compositions retain their uniformity over extended periods of time on tool. The ligand configuration according to the current disclosure has unexpectedly turned out to have much reduced redistribution tendency in comparison with other metal alkyl compounds of similar structure.

Further, precursor compounds with a ligand configuration described herein are more stable than expected against isomerization reactions that are common for metal complexes containing bulky alkyl ligands such as tert-butyl groups. The stability of a precursor compound according to the current disclosure may increase precursor shelf-life, on-tool stability at the evaporation temperature, as well as reduction of decomposition during vapor deposition. Especially the stability during deposition may be important in atomic layer deposition-type processes, where self-limiting growth of the deposited material is targeted.

As a further advantage of the compositions according to the current disclosure, they may have high enough vapor pressure to allow their use with moderate heating. This may allow them to be used in vapor deposition processes having a limited thermal budget.

In some embodiments, the composition according to the current disclosure comprises at least 80 w-% of metal alkyl precursor. In some embodiments, the composition according to the current disclosure comprises at least 90 w-% of metal alkyl precursor. In some embodiments, the composition according to the current disclosure comprises at least 92 w-% of metal alkyl precursor. In some embodiments, the composition according to the current disclosure comprises at least 95 w-% of metal alkyl precursor. In some embodiments, the composition according to the current disclosure comprises at least 98 w-% of metal alkyl precursor. In some embodiments, the composition according to the current disclosure consists essentially of metal alkyl precursor. In some embodiments, the composition according to the current disclosure consists of metal alkyl precursor. Thus, the composition according to the current disclosure may comprise at least 80 w-%, at least 85 w-%, at least 90 w-%, at least 92 w-%, at least 95 w-% or at least 98 w-% of bis(tert-butyl)methylaluminum. In some embodiments, the composition according to the current disclosure comprises at least 80 w-%, at least 85 w-%, at least 90 w-%, at least 92 w-%, at least 95 w-% or at least 98 w-% of bis(tert-butyl)methylgallium. In some embodiments, the composition according to the current disclosure may comprise at least 80 w-%, at least 85 w-%, at least 90 w-%, at least 92 w-%, at least 95 w-% or at least 98 w-% of bis(tert-butyl)methylindium.

Compositions used in semiconductor applications are preferentially pure to ascertain the reproducibility, transferability and scalability of a deposition process. In some embodiments, the composition may contain related compounds of the metal alkyl precursor, such as the corresponding compound comprising three ligands of first ligand type or two ligands of the second ligand type. The composition may also comprise compounds derived from isomerization of the first ligand type ligands.

The purity of the composition according to the current disclosure may be measured as, for example, the ratio of first and second ligand type ligands. In a composition comprising only the targeted metal alkyl precursor, the ratio of ligands of first ligand type to ligands of second ligand type, for example ratio of tert-butyl to methyl, would be 2. In some embodiments, the ratio of first ligand type ligands to second ligand type ligands is about 1.90, about 1.95, about 1.99, about 2.05 or about 2.10. In some embodiments, the ratio of first ligand type ligands to second ligand type ligands is between about 1.90 and 2.05. In some embodiments, said ratio is between about 1.95 and 2.10. In some embodiments, the ratio of first ligand type ligands to second ligand type ligands is between about 1.95 and 2.05.

In some embodiments, the composition according to the current disclosure comprises at most 10 w-% of other substances than the metal alkyl precursor. In some embodiments, the composition according to the current disclosure comprises at most 8 w-% of other substances than the metal alkyl precursor. In some embodiments, the composition according to the current disclosure comprises at most 5 w-% of other substances than the metal alkyl precursor. In some embodiments, the composition according to the current disclosure comprises at most 2 w-% of other substances than the metal alkyl precursor. In some embodiments, the amount of other substances than the metal alkyl precursor is below detection limits of NMR spectroscopy.

In some embodiments, the vapor pressure of the composition according to the current disclosure is about 1 Torr or more at a temperature of 20° C. or higher. In some embodiments, the vapor pressure of the composition may be about 1 Torr or more at a temperature of 50° C. or higher. In some embodiments, the vapor pressure of the composition may be about 1 Torr or more at a temperature of 60° C. or higher. In some embodiments, the vapor pressure of the composition may be about 1 Torr or more at a temperature of 70° C. or higher. In some embodiments, the vapor pressure of the composition may be about 1 Torr or more at a temperature of 100° C. or higher. In some embodiments, the vapor pressure of the composition may be about 1 Torr or more at a temperature of 120° C. or higher. In some embodiments, the vapor pressure of the composition may be about 1 Torr or more at a temperature of 150° C. or higher. In some embodiments, the vapor pressure of the composition may be about 1 Torr or more at a temperature of 180° C. or higher.

For example, in some embodiments, the vapor pressure of the composition according to the current disclosure is about 1 Torr or more at a temperature of 20° C. to 50° C. In some embodiments, the vapor pressure of the composition according to the current disclosure is about 1 Torr or more at a temperature of 50° C. to 100° C. In some embodiments, the vapor pressure of the composition according to the current disclosure is about 1 Torr or more at a temperature of 70° C. to 150° C. In some embodiments, the vapor pressure of the composition according to the current disclosure is about 1 Torr or more at a temperature of 100° C. to 170° C.

In some embodiments, the vapor pressure of the composition is about 1 Torr at a temperature of 65° C. In some embodiments, the vapor pressure of the composition is about 10 Torr at 90° C. In some embodiments, the vapor pressure of the composition is about 1 Torr at a temperature of 64 to 69° C. In some embodiments, the vapor pressure of the composition is about 3 Torr at a temperature of 70 to 74° C. In some embodiments, the vapor pressure of the composition is about 5 Torr at a temperature of 75 to 79° C. In some embodiments, the vapor pressure of the composition is about 7 Torr at a temperature of 80 to 84° C.

The stability of the composition according to the current disclosure may be measured as, for example, by determining ¹H NMR spectrum of the sample, which can be used to detect ligand isomerization. In some embodiments, the composition according to the current disclosures is stable at a temperature of 62° C. for at least ten weeks.

In some embodiments, the composition may be solid at standard temperature and pressure. In some embodiments, the composition is solid in ambient pressure at temperatures under 120° C. Thus, for vapor deposition processes, the composition according to the current disclosure may be used as a solid composition. Without limiting the current disclosure to any specific theory, it may be that the stability of the composition may be at least in part due to the solid form of the composition. The relatively high vapor pressure and stability may allow the use of the current composition in various processes, also when low deposition temperatures are needed. Thus, in some embodiments, the composition according to the current disclosure is suitable for depositing group 13 metal-containing material on the substrate by a vapor deposition process. In some embodiments, aluminum-containing material is deposited. In some embodiments, gallium-containing material is deposited. In some embodiments, indium-containing material is deposited.

In an aspect, the current disclosure relates to a method of producing a composition according to the current disclosure. The method comprises reacting bis(methyl)tert-butylaluminum with aluminumtrichloride and tert-butyllithium as described below to obtain bis(tert-butyl)methylaluminum. In some embodiments, bis(methyl)tert-butylaluminum is reacted with aluminum trichloride and tert-butyllithium in a molar ratio of 1:1:3. This reaction may proceed by transference of a tert-butyl group from lithium to aluminumtrichloride with removal of chloride driven by the formation of lithium chloride as an easily removed by-product. Alkyl ligand exchange reactions between the bis(methyl)tert-butylaluminum starting material and the newly generated tert-butyl bearing aluminum species may produce the target molecule in high yield. The yield may depend on the ratio of reactants, which may be adjusted with methods known in the art.

In some embodiments, the method of producing a composition according to the current disclosure comprises purification of bis(tert-butyl)methylaluminum from the reaction mixture. Bis(tert-butyl)methylaluminum may be purified by filtration to remove aluminum trichloride. The bis(tert-butyl)methylaluminum may be purified by fractional sublimation. In such methods, the solvent used in the reaction may be evaporated first. Next, bis(tert-butyl)methylaluminum may be collected on a condenser of a sublimation apparatus leaving non-volatile components to the residual fraction.

Alternatively or in addition, salts, such as chlorides, may be removed from the reaction mixture by filtration.

In one aspect, a method of producing a composition according to the current disclosure, wherein the method comprises reacting tris(tert-butyl)aluminum with trimethylaluminum to obtain bis(tert-butyl)methylaluminum, is disclosed.

In another aspect, a method of producing a composition according to the current disclosure, wherein the method comprises reacting trimethylaluminum with aluminumtrichloride and tert-butyllithium to obtain bis(tert-butyl)methylaluminum, is disclosed.

In yet another aspect, a method of depositing group 13 metal-containing material on a substrate using the composition according to the current disclosure is disclosed. In some embodiments, the group 13 metal-containing material is deposited by a vapor deposition process. The vapor deposition process may be a cyclical vapor deposition process, such as ALD or cyclic CVD process. The method of depositing group 13 metal-containing material on a substrate may comprise providing a substrate in a reaction chamber, providing a the composition according to the current disclosure into the reaction chamber in a vapor phase; and providing a second reactant to the reaction chamber in a vapor phase to form group 13 metal-containing material on the substrate. As described above, the material may be, for example, aluminum-, indium- or gallium-containing material.

In some embodiments of the method, the group 13 metal deposited on the substrate is selected from a group consisting of aluminum, gallium and indium. In some embodiments, aluminum-containing material is deposited. In some embodiments, gallium-containing material is deposited. In some embodiments, indium-containing material is deposited.

Thus, in one aspect, a composition according to the current disclosure for use in a vapor deposition process is disclosed. In a further aspect, use of a composition according to the current disclosure to deposit a group 13 metal-containing material on a substrate is disclosed.

The chemical composition of the deposited metal-containing material will be influenced by the second reactant. Therefore, the second reactant will be selected according to the application in question. The specific deposition conditions may vary according to the application in question. In some embodiments, the method of depositing a group 13 metal-containing material comprises pulsing the composition according to the current disclosure into the reaction chamber. In some embodiments, the method comprises pulsing the second reactant into the reaction chamber. In some embodiments, the method comprises purging the reaction chamber between reactant pulses.

As used herein, the term “purge” may refer to a procedure in which an inert or substantially inert gas is provided to a reactor chamber in between two pulses of gases which react with each other. However, purging may be effected between two pulses of gases that do not react with each other. For example, a purge, or purging, for example by using nitrogen gas, may be provided between pulses of two precursors or between a precursor and a reducing agent. Purging may avoid or at least reduce gas-phase interactions between the two gases reacting with each other. It shall be understood that a purge can be effected either in time or in space, or both. For example in the case of temporal purges, a purge step can be used e.g. in the temporal sequence of providing a first precursor to a reactor chamber, providing a purge gas to the reactor chamber, and providing a second precursor to the reactor chamber, wherein the substrate on which a layer is deposited does not move. For example in the case of spatial purges, a purge step can take the following form: moving a substrate from a first location to which a first precursor is continually supplied, through a purge gas curtain, to a second location to which a second precursor is continually supplied.

The method of depositing group 13-containing material according to the current disclosure comprises providing a substrate in a reaction chamber. In other words, a substrate is brought into space where the deposition conditions can be controlled. The reaction chamber may be part of a cluster tool in which different processes are performed to form an integrated circuit. In some embodiments, the reaction chamber may be a flow-type reactor, such as a cross-flow reactor. In some embodiments, the reaction chamber may be a showerhead reactor. In some embodiments, the reaction chamber may be a space-divided reactor. In some embodiments, the reaction chamber may be single wafer ALD reactor. In some embodiments, the reaction chamber may be a high-volume manufacturing single wafer ALD reactor. In some embodiments, the reaction chamber may be a batch reactor for manufacturing multiple substrates simultaneously.

In an aspect, a reactant vessel containing a composition according to the current disclosure is disclosed. A chemical reactant delivery system for vapor deposition can include a reactant vessel for providing a reactant into a reaction chamber. The reactant delivery system may comprise a heating means including a heater, such as a radiant heat lamps, resistive heaters etc. In some embodiments, the heating means may be adapted to heat the reactant vessel to a temperature from about 40° C. to about 140° C., such as to about 70° C., 85° C., 90° C., 110° C. or 120° C. In some embodiments, the heating means may be adapted to heat the reactant vessel to a temperature from about 50° C. to about 140° C. In some embodiments, the heating means may be adapted to heat the reactant vessel to a temperature from about 60° C. to about 140° C. In some embodiments, the heating means may be adapted to heat the reactant vessel to a temperature from about 80° C. to about 140° C. In some embodiments, the heating means may be adapted to heat the reactant vessel to a temperature from about 100° C. to about 140° C. In some embodiments, the heating means may be adapted to heat the reactant vessel to a temperature from about 40° C. to about 120° C. In some embodiments, the heating means may be adapted to heat the reactant vessel to a temperature from about 40° C. to about 100° C. In some embodiments, the heating means may be adapted to heat the reactant vessel to a temperature from about 40° C. to about 80° C. In some embodiments, the heating means may be adapted to heat the reactant vessel to a temperature from about 40° C. to about 70° C.

The reactant vessel includes the solid composition according to the current disclosure. The heater heats up the reactant vessel to vaporize the reactant in the reactant vessel. The reactant vessel can have an inlet and an outlet for the flow of a carrier gas (e.g., N₂) through the reactant vessel. The carrier gas may be an inert gas. The carrier gas may sweep reactant vapor, for example sublimated reactant, along with it through the reactant vessel outlet and ultimately to a substrate in a reaction chamber. The reactant vessel typically includes isolation valves for fluidly isolating the contents of the reactant vessel from the vessel exterior. One isolation valve may be provided upstream of the reactant vessel inlet, and another isolation valve may be provided downstream of the reactant vessel outlet.

The composition according to the current disclosure may be solid at standard pressure and temperature. Depending on the application, the composition may be heated and/or maintained at very low pressures to produce a sufficient amount of reactant vapor for the vapor deposition process.

Once vaporized (sublimed), it is important that the vapor phase reactant is kept at or above the vaporizing temperature through the processing system so as to prevent undesirable condensation in the valves, filters, conduits, and other components associated with delivering the vapor phase reactants into the reaction chamber.

A reactant vessel may be supplied with gas lines extending from the inlet and outlet, isolation valves on the lines, and fittings on the valves, the fittings being configured to connect to the gas flow lines of the remaining vapor deposition assembly. It is often desirable to provide a number of additional heaters for heating the various valves and gas flow lines between the reactant vessel and the reaction chamber, to prevent the reactant vapor from condensing and depositing on such components. Accordingly, the gas-conveying components between the reactant vessel and the reaction chamber are sometimes referred to as a “hot zone” in which the temperature is maintained above the vaporization/condensation/sublimation temperature of the reactant.

In some embodiments, a reactant vessel according to the current disclosure is configured and arranged for use in a vapor deposition assembly. In some embodiments, a reactant vessel according to the current disclosure contains bis(tert-butyl)methylaluminum. In some embodiments, a chemical reactant vessel according to the current disclosure contains bis(tert-butyl)methylgallium. In some embodiments, a chemical reactant vessel according to the current disclosure contains bis(tert-butyl)methylindium.

In still another aspect, a vapor deposition assembly comprising a reactant vessel according to the current disclosure is disclosed. The vapor deposition assembly includes a reaction chamber for depositing a group 13 metal-containing material on a substrate and a reactant delivery system comprising a reactant vessel according to the current disclosure connected to the reaction chamber to supply the metal alkyl precursor according to the current disclosure into the reaction chamber.

The vapor deposition assembly for depositing group 13 metal-containing material on a substrate comprises one or more reaction chambers constructed and arranged to hold the substrate and a precursor injector system constructed and arranged to provide a metal alkyl precursor according to the current disclosure into the reaction chamber in a vapor phase. The vapor deposition assembly further comprises a reactant vessel constructed and arranged to contain a composition according to the current disclosure and the assembly is constructed and arranged to provide a composition according to the current disclosure via the precursor injector system to the reaction chamber to deposit group 13 metal-containing material on the substrate.

In some embodiments, the vapor deposition assembly may additionally include control processors and software configured to operate the reaction chamber to perform an ALD process. In some embodiments, the vapor deposition assembly may additionally include control processors and software configured to operate the reaction chamber to perform a CVD process.

### DETAILED DESCRIPTION OF THE DRAWINGS

The disclosure is further explained by the following exemplary embodiments depicted in the drawings. The illustrations presented herein are not meant to be actual views of any particular material, structure, or device, but are merely schematic representations to describe embodiments of the current disclosure. It will be appreciated that elements in the figures are illustrated for simplicity and clarity and have not necessarily been drawn to scale. For example, the dimensions of some of the elements in the figures may be exaggerated relative to other elements to help improve the understanding of illustrated embodiments of the present disclosure. The structures and devices depicted in the drawings may contain additional elements and details, which may be omitted for clarity.

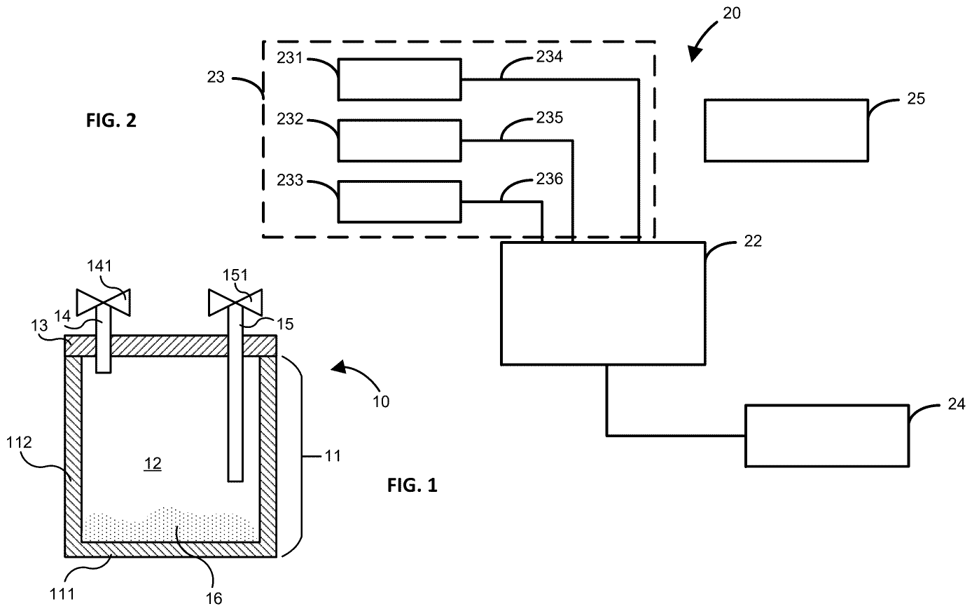

FIG. 1 illustrates a reactant vessel 10 according to the current disclosure. The reactant vessel 10 is fabricated of a suitable vessel material, such as stainless steel, aluminum, copper, nickel, silver, their alloys, graphite, boron nitride, ceramic material or a combination or a mixture of said materials. The reactant vessel 10 material may be heat-conducting material. The reactant vessel 10 material may be coated or clad material. The reactant vessel comprises a housing 11 defining an interior volume 12 of the reactant vessel 10. The interior volume 12 is adapted for holding a composition according to the current disclosure.

In FIG. 1, the reactant vessel 10 comprises a composition 16 according to the current disclosure. In the figure, the composition 16 is simply placed in the interior volume 12 of the vessel 10. However, various arrangements, are known in the art for improving or regulating the volatility of a composition in a reactant vessel. Any such arrangements, for example shelves, channels or compartments may be used in a reactant vessel 10 according to the current disclosure. Further, depending on the process for which the composition 16 is used, its scale, as well as the size of a precursor vessel 10, the degree of loading of the precursor in the reactant vessel 10 may vary. Thus, also in this respect, FIG. 1 is merely a schematic presentation of a possible degree of loading of composition 16, and more or less of it may be loaded into a precursor vessel 10.

The reactant vessel 10 may be coupled to heating means, such as a heater, for example radiant heat lamps or resistive heaters. The heating means heats up the reactant vessel 10 to enhance the vaporization of the precursor in the reactant vessel 10. The heating means may be internal or external to the reactant vessel 10.

The housing 11 of FIG. 1 comprises a floor 111, and a sidewall 112. In some embodiments, the housing 11 has a substantially circular cylindrical shape. Thus, the housing 11 has a circular floor 111. However, the reactant vessel 10 can have any shape that facilitates an even flow of carrier gas through the interior volume 12 thereof. In some embodiments, the reactant vessel 10 has substantially a shape of rectangular prism. The shape of the reactant vessel 10 may deviate from the above-mentioned ideal geometrical shapes due to usability, ease of manufacture and handling. For example, any edges and/or corners may be rounder, or some sides at least partially slanted. In some embodiments, a floor and a sidewall may not be discernable. The floor 111 may be curved. The housing 11 may be constructed from one part by, for example, machining. However, it is possible that the housing 11 is formed from two or more parts attached to each other in a gas-tight manner. For example, the floor 111 and the sidewall 112 may be separable.

The size and proportions of the reactant vessel 10 may vary according to design choices and application in question, as well as due to scale of vapor deposition process. In some embodiments, the height of the reactant vessel 10 is larger than its width. In some embodiments, the height of the reactant vessel 10 is equal to its width. In some embodiments, the height of the reactant vessel 10 is smaller than its width. In some embodiments, the reactant vessel 10 may have a height to width aspect ratio in the range of about 0.5 to 4, for example 1 to 2 or 1 to 3. The height of the reactant vessel 10 is the outside measurement of the reactant vessel 10 from the lid 13 to the portion of the housing 11 furthest away from the lid 13. The width of the reactant vessel 10 is the longest measurement across the reactant vessel 10 perpendicular to the height.

The reactant vessel 10 comprises a lid 13 for isolating the interior volume 12 from the surrounding atmosphere. The lid 13 may comprise an inlet 14 for feeding carrier gas into the reactant vessel 10. The inlet 14 may comprise an inlet valve 141, and the inlet 14 may be arranged to selectively introduce carrier gas into the interior volume 12 of the reactant vessel 10, when the inlet valve 141 is open. The lid 13 may comprise an outlet 15 for feeding carrier gas and vaporized precursor into a reaction chamber of a vapor deposition assembly (not shown). The outlet 15 may comprise an outlet valve 151 and be arranged to selectively release carrier gas containing vaporized precursor into reaction chamber when the outlet valve 151 is open. When connected to a vapor deposition assembly, gas lines may extend from the inlet 14 and outlet 15, isolation valves on the lines, and fittings on the valves, the fittings being configured to connect to the gas flow lines of the remaining vapor deposition assembly.

The reactant vessel 10 may comprise additional features that are omitted from the figure for clarity. For example, the reactant vessel 10 may comprise precursor distribution means for enabling efficient precursor vaporization. To this end, various precursor holding structures or carrier gas guiding arrangements may be present in the interior volume 12 of the reactant vessel 10. The reactant vessel 10 may comprise features for avoiding solid precursor particles from being caught in the carrier gas stream. Various filters or other entrapment structures may be used. Additionally, the inlet 14 and the outlet 15, as well as gas lines extending therefrom may comprise heaters for heating the various valves and gas lines between the reactant vessel 10 and the reaction chamber to prevent the reactant vapor from condensing and depositing on any components.

FIG. 2 illustrates a vapor deposition assembly 20 comprising a reactant vessel 231 according to the current disclosure in a schematic manner. The deposition assembly 20 can be used to perform a deposition method as described herein to deposit group 13 metal-containing material on a substrate. In the illustrated example, deposition assembly 20 includes one or more reaction chambers 22, a precursor injector system 23, a reactant vessel 231 for holding the composition according to the current disclosure, a second reactant vessel 232, a purge gas source 233, an exhaust source 24, and a controller 25.

Reaction chamber 22 can include any suitable reaction chamber, such as an ALD or CVD reaction chamber.

The reactant vessel 231 can include a vessel and a composition as described herein—alone or mixed with one or more carrier (e.g., inert) gases. A second reactant vessel 232 can include a vessel and one or more additional reactants—alone or mixed with one or more carrier gases. Purge gas source 233 can include one or more inert gases, such as N₂ or He or Ar. Although illustrated with three reactant vessels 231-233, deposition assembly 20 can include any suitable number of reactant vessels. Reactant vessels 231-233 can be coupled to reaction chamber 22 via lines 234-236, which can each include flow controllers, valves, heaters, and the like. In some embodiments, composition according to the current disclosure in the reactant vessel 231, and/or second reactant and/or purge gas may be heated. In some embodiments, the reactant vessel 231 is heated so that the composition according to the current disclosure reaches a temperature between about 50° C. and about 140° C., such as between about 70° C. and about 130° C., for example 60° C., 80° C., 90° C., 100° C., 110° C. or 120° C. Exhaust source 24 can include one or more vacuum pumps.

Controller 25 includes electronic circuitry and software to selectively operate valves, manifolds, heaters, pumps and other components included in the deposition assembly 20. Such circuitry and components operate to introduce precursors, reactants and purge gases from the respective sources 231-233. Controller 25 can control timing of gas pulse sequences, temperature of the substrate and/or reaction chamber 22, pressure within the reaction chamber 22, and various other operations to provide proper operation of the deposition assembly 20. Controller 25 can include control software to electrically or pneumatically control valves to control flow of precursors, reactants and purge gases into and out of the reaction chamber 22. Controller 25 can include modules such as a software or hardware component, which performs certain tasks.

Other configurations of deposition assembly 20 are possible, including different numbers and kinds of precursor and reactant sources and purge gas sources. Further, it will be appreciated that there are many arrangements of valves, conduits, precursor sources, and purge gas sources that may be used to accomplish the goal of selectively and in coordinated manner feeding gases into reaction chamber 22. Further, as a schematic representation of a deposition assembly, many components have been omitted for simplicity of illustration, and such components may include, for example, various valves, manifolds, purifiers, heaters, containers, vents, and/or bypasses.

During operation of deposition assembly 20, substrates, such as semiconductor wafers (not illustrated), are transferred from, e.g., a substrate handling system to reaction chamber 22. Once substrate(s) are transferred to reaction chamber 22, one or more gases from gas sources 231-233, such as precursors, reactants, carrier gases, and/or purge gases, are introduced into reaction chamber 22.

### EXAMPLES

In the below examples, the preparation of bis(tert-butyl)methylaluminum is described for experimental scale. However, the processes may be scalable for high volumes with modifications within the competence of the skilled person. For example, prior to distilling off the solvent as described in step 3, a filtration may be used to remove the insoluble LiCl salt by-product. Distilling off the solvent after filtration may then be expected to generate the desired tBu₂AlMe product in suitable purity (>95% pure) without completing the sublimation.

In the below examples, tBu stands for tert-butyl, and Me stands for methyl.

### Example 1 Preparation of Bis(Tert-Butyl)Methylaluminum from Bismethyl(Tert-Butyl)Aluminum

The starting material for tBuAlMe₂ may be prepared as described in literature (Jones et al. Journal of Crystal Growth, 1989, 96: 769-773) was used as a starting material. Shortly, the tBuAlMe₂ synthesis method involves addition of tert-butyllithium to a solution of Me₂AlCl in a non-polar aliphatic solvent such as hexanes. The Me₂AlCl solution may either be purchased from a commercial supplier or prepared by combining AlMe₃ and AlCl₃ in a 2 to 1 molar ratio in the same solvent.

The synthesis of bis(tert-butyl)methylaluminum was performed according to the chemical reaction of scheme (I).

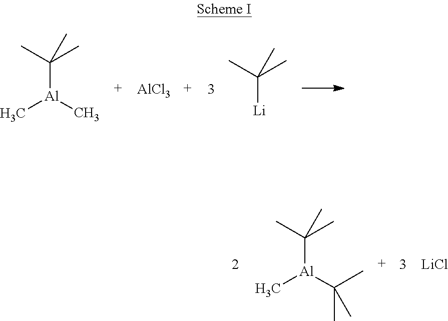

tBu₂AlMe was prepared using the steps described below. All steps were carried out with rigorous exclusion of oxygen and moisture using standard inert-atmosphere techniques.

Step 1: Combine tBuAlMe₂ with AlCl₃ in a 1:1 Molar Ratio

First, 52.6 grams (394 mmol) of AlCl₃ was placed into a 3-litre round-bottom flask equipped with a PTFE-coated magnetic stirring bar. 700 mL of anhydrous hexanes was added to the flask, and stirring of the resulting suspension was initiated. 45.0 grams (394 mmol) of tBuAlMe₂ was added to the flask. The mixture was stirred at ambient temperature for one hour, resulting in dissolution of all AlCl₃ to give a clear colourless solution.

Step 2: Addition of tBuLi

The contents of the flask were cooled using a −78° C. cold bath, stirring was continued. When the temperature of the reaction mixture had fallen to −30° C., slow addition of a pentane solution of tBuLi (1.69M, 700 mL, 1.18 mol) was initiated. The addition was completed over a period of approximately 30 minutes. Stirring of the mixture was continued overnight in the cooling bath (approximately 18 hours), during which time the system gradually warmed to room temperature, bringing the reaction to completion.

### Step 3: Removal of Solvent

The reaction mixture was placed in a heating mantle set to a temperature of 40° C. With stirring, the reaction solvent was distilled off under a vacuum controlled at 10 Torr. When the bulk of solvent had been removed, the vacuum level was reduced to 1 Torr to evaporate remaining residual solvent. The crude product, consisting of a mixture of tBu₂AlMe and LiCl was left in the flask in the form of a white powder.

Step 4: Separation of tBu₂AlMe from LiCl Salts.

The crude reaction product obtained from Step 3 was transferred to the chamber of a bulk sublimation apparatus. Purified tBu2AlMe was collected on a condenser over a period of approximately 6 hours in a vacuum of (pressure <100 mTorr), at a chamber temperature of 90° C. and condenser temperature of −20° C., leaving the non-volatile LiCl by-product in the chamber. 105 grams (876 mmol, 77% Yield) of tBuAlMe₂ (>95% pure) was obtained from the condenser.

### Example 2 Preparation of Bis(Tert-Butyl)Methylaluminum from Trimethylaluminum

Similarly, tBu2AlMe can be prepared using the commercially available reagents AlMe₃, AlCl₃, and tBuLi, according to the following reaction scheme (Scheme 11). A 4-step synthetic process similar to Example 1 can be used, with only the differences for each step compared to Example I written out.

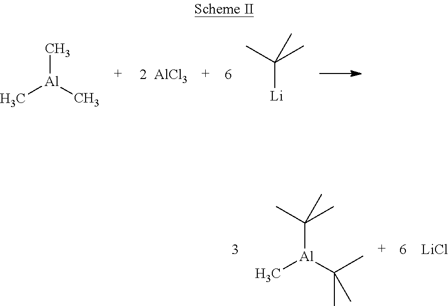

Step 1: Combine AlMe₃ with AlCl₃ in a 1:2 Molar Ratio

Combine AlMe₃ (100 mL, 2.0M in hexanes, 200 mmol) with AlCl₃ (400 mmol) in a 1:2 molar ratio, and stir until the system comes to equilibrium.

Step 2: Addition of tBuLi

Add tBuLi (approximately 1.7M in hexanes, approximately 700 mL, 1.20 mol) under the same conditions used in original process described above.

### Steps 3 and 4

The final steps required to isolate the product can be completed as in Example 1.

1. A method of depositing a group 13 metal-containing material on a substrate comprising:
providing the substrate in a reaction chamber; and
depositing the group 13 metal-containing material on the substrate using a cyclic vapor deposition process comprising:
pulsing a composition comprising a metal alkyl precursor into the reaction chamber,
pulsing a reactant into the reaction chamber, and
purging the reaction chamber before and/or after the pulsing the composition,
wherein the metal alkyl precursor comprises a group 13 metal atom and two different alkyl ligand types, where a first ligand type is a branched C4 to C8 alkyl bonded to the group 13 metal atom through a carbon atom that is bonded to three carbon atoms, a second ligand type is a linear C1 to C4 alkyl, and a ratio of the first ligand type to the second ligand type is two to one.

2. The method of claim 1, wherein the method comprises a cyclic vapor deposition process.

3. The method of claim 1, wherein the method comprises an atomic layer deposition process.

4. The method of claim 1, wherein the pulsing the composition and the pulsing the reactant overlap only partially.

5. The method of claim 1, wherein the group 13 metal-containing material is metallic.

6. The method of claim 1, wherein the group 13 metal-containing material comprises a ternary material.

7. The method of claim 6, wherein the ternary material comprises silicon oxide.

8. The method of claim 1, wherein the group 13 metal-containing material comprises a metal alloy.

9. The method of claim 1, further comprising purifying the metal alkyl precursor by fractional sublimation.

10. The method of claim 1, wherein the method comprises depositing carbon-containing material.

11. The method of claim 1, wherein a vaporization rate of the precursor is substantially constant during the deposition process.

12. The method of claim 1, wherein the first ligand type is a saturated hydrocarbon.

13. The method of claim 1, wherein the first ligand type comprises one or more double bonds.

14. The method of claim 1, wherein two ligands of the first ligand type form a substituted metallacycle with the group 13 metal atom.

15. The method of claim 14, wherein the substituted metallacycle comprises substituted metallacyclopentane or substituted metallacyclohexane.

16. The method of claim 1, wherein the metal alkyl precursor comprises a dimer.

17. The method of claim 16, wherein at least fifty percent of the metal alkyl precursor is present as a dimer in a solid composition.

18. The method of claim 1, wherein the metal alkyl precursor is a solid at standard temperature and pressure.
